(19) United States
(12) Patent Application Publication
(10) Pub. No.: US 2024/0136264 A1
(43) Pub. Date: Apr. 25, 2024

(54) FAN-OUT SEMICONDUCTOR PACKAGE AND METHOD OF MANUFACTURING THE FAN-OUT SEMICONDUCTOR PACKAGE

(71) Applicant: SAMSUNG ELECTRONICS CO., LTD., Suwon-si (KR)

(72) Inventors: Chiwan SONG, Suwon-si (KR); Hyunna BAE, Suwon-si (KR); Joohyung LEE, Suwon-si (KR); Jaewook JUNG, Suwon-si (KR); Seungmin BAEK, Suwon-si (KR); Junghyun CHO, Suwon-si (KR)

(21) Appl. No.: 18/374,792

(22) Filed: Sep. 28, 2023

(30) Foreign Application Priority Data
Oct. 24, 2022 (KR) 10-2022-0138018

(51) Int. Cl. H01L 23/498; H01L 23/00; H01L 23/48; H01L 25/10

(52) U.S. Cl. CPC H01L 23/49822; H01L 23/481; H01L 23/49816; H01L 24/08; H01L 25/105; H01L 24/48; H01L 2224/08225; H01L 2224/48145; H01L 2224/48227

(57) ABSTRACT

A semiconductor package includes: a chip-via composite substrate including a substrate, a semiconductor chip, and a plurality of through vias, wherein the substrate has a first surface and a second surface opposite to the first surface and includes a first region and a second region around the first region, wherein the semiconductor chip is provided in the first region and has chip pads and circuit patterns that are electrically connected to the chip pads, and wherein the plurality of through vias is provided in the second region and penetrate the substrate; a first redistribution wiring layer provided on the first surface of the substrate and having first redistribution wirings that are electrically connected to the chip pads and the through vias; and a second redistribution wiring layer provided on the second surface of the substrate and having second redistribution wirings that are electrically connected to the through vias.

### CROSS-REFERENCE TO RELATED APPLICATION

This application claims priority under 35 U.S.C. § 119 to Korean Patent Application No. 10-2022-0138018, filed on Oct. 25, 2022 in the Korean Intellectual Property Office (KIPO), the disclosure of which is incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a fan-out semiconductor package and a method of manufacturing the same.

### DISCUSSION OF THE RELATED ART

Generally, in manufacturing a fan-out wafer level package, copper posts may be formed on a lower redistribution wiring layer, and a semiconductor chip may be mounted on the lower redistribution wiring layer. An upper redistribution wiring layer may be formed on the semiconductor chip to be electrically connected to the copper posts. However, the process of forming the copper posts may be difficult and complicated, and heat dissipation characteristics may be deteriorated due to a sealing material sealing the copper posts and the semiconductor chip.

### SUMMARY

According to an example embodiment of the present inventive concept, a semiconductor package includes: a chip-via composite substrate including a substrate, a semiconductor chip, and a plurality of through vias, wherein the substrate has a first surface and a second surface opposite to the first surface and includes a first region and a second region around the first region, wherein the semiconductor chip is provided in the first region and has chip pads, which are formed on the first surface, and circuit patterns that are electrically connected to the chip pads, and wherein the plurality of through vias is provided in the second region and penetrate the substrate; a first redistribution wiring layer provided on the first surface of the substrate and having first redistribution wirings that are electrically connected to the chip pads and the through vias; and a second redistribution wiring layer provided on the second surface of the substrate and having second redistribution wirings that are electrically connected to the through vias.

According to an example embodiment of the present inventive concept, a semiconductor package includes: a chip-via composite substrate including a substrate, a front insulating layer, and a plurality of through vias, wherein the substrate has a first surface and a second surface opposite to the first surface and includes a first region and a second region around the first region, wherein the front insulating layer is provided on the first surface of the substrate and has chip pads adjacent to an outer surface of the front insulating layer, wherein circuit patterns are provided on the first surface of the substrate and are electrically connected to the chip pads, and wherein the plurality of through vias is provided in the second region and penetrate the front insulating layer and the substrate; a first redistribution wiring layer provided on the first surface of the substrate and having first redistribution wirings that are electrically connected to the chip pads and the through vias; and a second redistribution wiring layer provided on the second surface of the substrate and having second redistribution wirings that are electrically connected to the through vias.

According to an example embodiment of the present inventive concept, a semiconductor package includes: a chip-via composite substrate having a first surface and a second surface opposite to the first surface, and including a semiconductor chip and a plurality of through vias, wherein the semiconductor chip is provided in a first region of the chip-via composite substrate and has chip pads that are exposed from the first surface, and wherein the plurality of through vias are provided in a second region of the chip-via composite substrate and extend from the first surface to the second surface; a first redistribution wiring layer provided on the first surface of the chip-via composite substrate and having first redistribution wirings that are electrically connected to the chip pads and the through vias; and a second redistribution wiring layer provided on the second surface of the chip-via composite substrate and having second redistribution wirings that are electrically connected to the through vias.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a semiconductor package in accordance with an example embodiment of the present inventive concept.

FIG. 2 is an enlarged cross-sectional view illustrating portion ‘A’ in FIG. 1.

FIG. 3 is a plan view illustrating a base substrate in FIG. 1.

FIGS. 4, 5, 6, 7, 8, 9, 10, 11, 12, 13, 14, 15, 16, and 17 are views illustrating a method of manufacturing a semiconductor package in accordance with an example embodiment of the present inventive concept.

FIG. 18 is a cross-sectional view illustrating a semiconductor package in accordance with an example embodiment of the present inventive concept.

### DETAILED DESCRIPTION OF THE EMBODIMENTS

Hereinafter, example embodiments of the present inventive concept will be explained in detail with reference to the accompanying drawings.

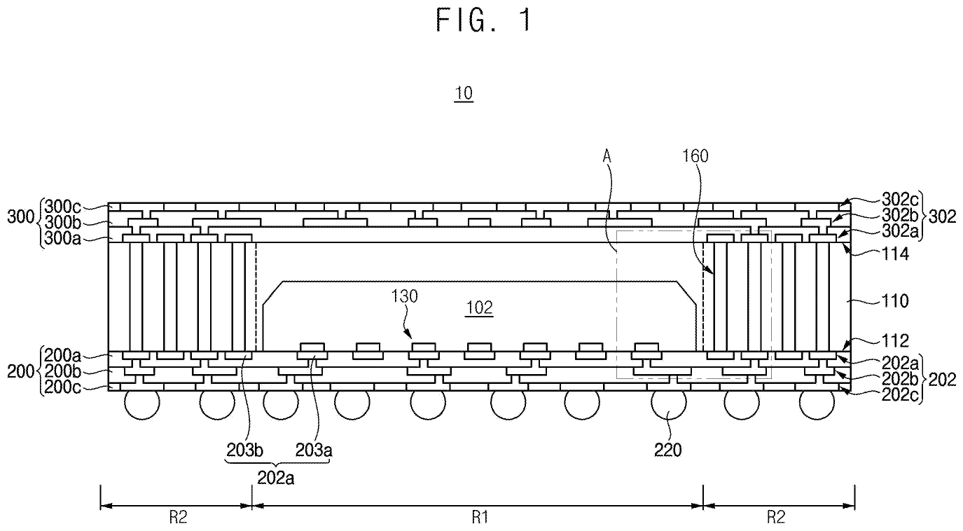

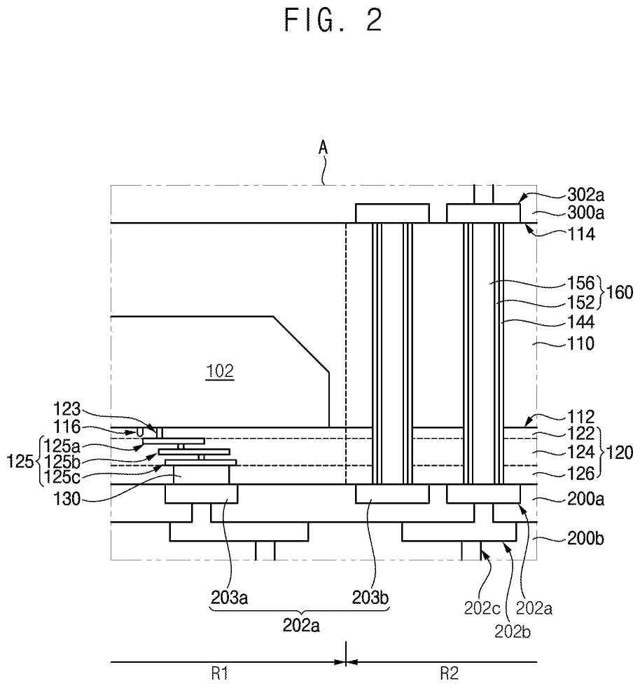

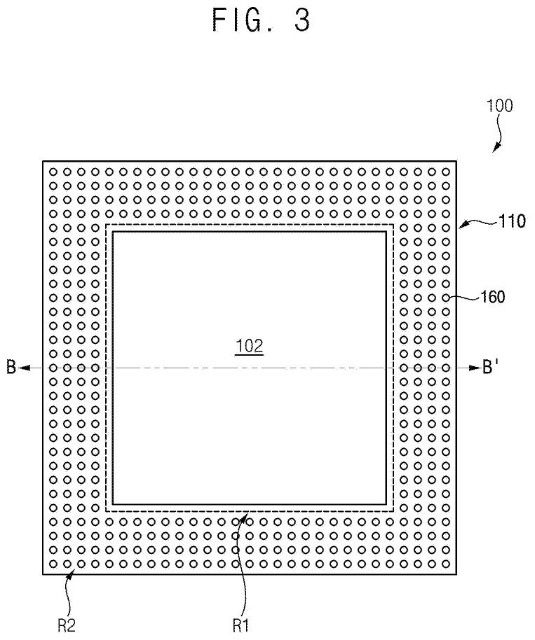

FIG. 1 is a cross-sectional view illustrating a semiconductor package in accordance with an example embodiment of the present inventive concept. FIG. 2 is an enlarged cross-sectional view illustrating portion ‘A’ in FIG. 1. FIG. 3 is a plan view illustrating a base substrate in FIG. 1. FIG. 1 is a cross-sectional view taken along the line B-B′ in FIG. 3.

Referring to FIGS. 1 to 3, a semiconductor package 10 may include a chip-via composite substrate 100, a first redistribution wiring layer 200 and a second redistribution wiring layer 300. In addition, the semiconductor package 10 may further include external connection members 220.

In addition, the semiconductor package 10 may be a fan-out wafer level package (FOWLP). The semiconductor package 10 may be used as a fan-out package on package (FO Package On Package). The semiconductor package 10 may be a multi-chip package (MCP) including different types of semiconductor chips. The semiconductor package 10 may be a system in package (SIP) having an independent function by stacking or arranging a plurality of semiconductor chips in one package.

In some example embodiments of the present inventive concept, the chip-via composite substrate 100 may include a semiconductor chip 102, which is provided in a first region R1, and a plurality of through vias 160, which are provided in a second region R2 at least partially surrounding the first region 104. The chip-via composite substrate 100 may include a substrate 110, a front insulating layer 120, a plurality of chip pads 130 and a plurality of through vias 160.

When viewed from a plan view, the chip-via composite substrate 100 may include the first region R1 positioned in a central region of the chip-via composite substrate 100 and the second region R2 at least partially surrounding the first region R1. The first region R1 may be a semiconductor chip region in which the semiconductor chip 102 is provided, and the second region R2 may be a peripheral region in which the plurality of through vias 160 are arranged outside the semiconductor chip 102.

For example, the substrate 110 may have a first surface 112 and a second surface 114 opposite to the first surface 112. The first surface 112 may be an active surface, and the second surface 114 may be an inactive surface. Circuit patterns 116 may be provided on the first surface 112 of the substrate 110. The first surface 112 may be referred to as a front side surface on which the circuit patterns are formed, and the second surface 114 may be referred to as a backside surface.

In some example embodiments of the present inventive concept, the front insulating layer 120 may be formed on the first surface 112, that is, the front surface of the substrate 110. The front insulating layer 130 may include an insulation interlayer 122, a metal wiring layer 124 and a passivation layer 126. In addition, the chip pads 130 may be provided in an outermost insulating layer of the front insulating layer 120. For example, the chip pads 130 may be adjacent to a bottom surface of the front insulating layer 120.

The insulation interlayer 122 may be formed on the first surface 112 of the substrate 110, i.e., the front surface, to cover the circuit patterns 116. The insulation interlayer 122 may be formed to include, for example, silicon oxide or a low dielectric material.

The metal wiring layer 124 may include a plurality of buffer layers and insulating layers alternately stacked on one another. For example, the buffer layer may include silicon nitride, silicon carbon nitride, SiCON, etc. The insulating layer may include, for example, silicon oxide, carbon-doped silicon oxide, silicon carbonitride (SiCN), etc.

The metal wiring layer 124 may include a plurality of wirings 125 therein. For example, the metal wiring layer 124 may include a metal wiring structure including the plurality of wirings 123 vertically stacked in the buffer layers and the insulating layers. The plurality of wirings may include a first metal wiring 125a, a first via V1, a second metal wiring 125b, a second via V2 and a third metal wiring 125c. The wiring may include, for example, aluminum (Al), copper (Cu), tin (Sn), nickel (Ni), gold (Au), platinum (Pt) or an alloy thereof.

The passivation layer 126 may be formed on the metal wiring layer 124 and may expose at least portions of the chip pads 130. The passivation layer 126 may include a plurality of stacked insulating layers. For example, the passivation layer 126 may include an organic passivation layer, which includes an oxide layer, and an inorganic passivation layer, which includes a nitride layer, sequentially stacked on each other. The passivation layer 126 may include, for example, silicon oxide, silicon nitride, silicon carbonitride, etc.

The chip pad 130 may be formed on the third metal wiring 125c which is an uppermost wiring of the metal wiring layer 124. The chip pad 130 may be exposed by the passivation layer 126. The first metal wiring 125a may be electrically connected to the circuit pattern 116 through a contact plug 123 penetrating the insulation interlayer 122. Accordingly, the circuit pattern 116 may be electrically connected to the chip pad 130 by the contact plug 123 and the metal wirings 125.

The semiconductor chip 102 may be provided in the first region R1 of the substrate 110, and the chip pads 130 may be provided in the outer surface of the front insulating layer 120 in the first region R1 of the substrate 110.

The semiconductor chip 102 may be logic chips including logic circuits. The logic chip may be a controller that controls memory chips. The semiconductor chips 102 may be a processor chip such as application processor (AP), ASICs serving as a host such as CPU, NPU, GPU, SOC, etc.

In some example embodiments of the present inventive concept, the through vias 160 as through-silicon vias (TSVs) may be provided in the second region R2. The through vias 160 may be provided to vertically penetrate the front insulating layer 120 and the substrate 110 from the first surface 112 to the second surface 114 of the substrate 110. A first end portion of the through via 160 may be exposed from a front surface of the chip-via composite substrate 100, that is, the front insulating layer 120. A second end portion of the through via 160 opposite to the first end portion may be exposed from a backside surface of the chip-via composite substrate 100, that is, the second surface 114 of the substrate 110.

The chip pads 130 may be arranged in an array form on the upper surface of the semiconductor chip 102 in the first region R1 of the substrate 110, and the through vias 160 may be arranged in an array form in the second region R2 of the substrate 110.

For example, a thickness of the substrate 110 may be within a range of about 100 μm to about 800 μm. A diameter of the through via 160 may be within a range of about 1 μm to about 50 μm.

In some example embodiments of the present inventive concept, the first redistribution wiring layer 200 as a front redistribution wiring layer may be provided on the front surface of the chip-via composite substrate 100, that is, on the front insulating layer 120. The first redistribution wiring layer 200 may include first redistribution wirings 202 that may be electrically connected to the chip pads 130 and through vias 160. The first redistribution wiring layer 200 may include first, second and third lower insulating layers 200a, 200b and 200c, which are stacked on one another, and the first redistribution wirings 202, which are in the stacked first, second and third lower insulating layers 200a, 200b and 200c. The first redistribution wirings 202 may include first, second and third lower redistribution wirings 202a, 202b and 202c. For example, a thickness of the first redistribution wiring layer 200 may be within a range of about 5 μm to about 50 μm.

The uppermost redistribution wirings 202a of the first redistribution wirings 202 may include first uppermost redistribution wirings 203a and second uppermost redistribution wirings 203b. The first uppermost redistribution wirings 203a may be arranged in the first region R1 and may be electrically connected to the chip pads 130 of the semiconductor chip 102, and second uppermost redistribution wirings 203b may be arranged in the second region R2 and may be electrically connected to the through vias 160.

The third lower insulating layer 200c may expose at least portions of the third lower redistribution wirings 202c. The third lower insulating layer 200c may serve as a passivation layer. A bump pad such as an under bump metallurgy (UBM) may be provided on the third lower redistribution wiring 202c that is exposed by the third lower insulating layer 200c. In this case, the exposed portion of the third lower redistribution 202c may serve as a landing pad, that is, a package pad.

The numbers, sizes, arrangements, etc. of the lower insulating layers and the lower redistribution wirings of the first redistribution wiring layer are provided as examples, and it will be understood that the present inventive concept is not limited thereto.

In some example embodiments of the present inventive concept, the second redistribution wiring layer 300 serving as a backside redistribution wiring layer may be provided on the backside surface of the chip-via composite substrate 100, that is, on the second surface 114 of the substrate 110. The second redistribution wiring layer 300 may include second redistribution wirings 302. The second redistribution wirings 302 may be electrically connected to the through vias 160. The second redistribution wiring layer 300 may include first to third upper insulating layers 300a, 300b and 300c, which are stacked on one another, and the second redistribution wirings 302, which are in the stacked first to third upper insulating layers 300a, 300b and 300c. The second redistribution wiring 302 may include first, second and third upper redistribution wirings 302a, 302b and 302c.

The first upper redistribution wirings 302a of the second redistribution wirings 302 may be electrically connected to the through vias 160 that is arranged in the second region R2. For example, the first upper redistribution wirings 302a may be directly connected to the through vias 160.

The third upper insulating layer 300c may have openings that respectively expose portions of the third upper redistributive wirings 302c. The third upper redistribution wirings 302c that are exposed by the openings may be outermost redistribution wirings. A portion of the outermost redistribution may include a redistribution pad portion. For example, a bump pad such as a UBM may be formed on the redistribution pad portion.

The numbers, sizes, arrangements, etc. of the upper insulating layers and the upper redistribution wirings of the second redistribution wiring layer are provided as examples, and it will be understood that the present inventive concept is not limited thereto.

In some example embodiments of the present inventive concept, external connection members 220 for electrical connection with an external device may be disposed on the package pads on the outer surface of the first redistribution wiring layer 200. For example, the external connection member 220 may be a solder ball or a solder bump. The semiconductor package 10 may be mounted on a module substrate via the external connection members 220.

Some of the external connection members 220 may be disposed in the second region R2 outside the first region R1 where the semiconductor chip 102 is disposed. Accordingly, the semiconductor package 10 may be provided as a fan-out package.

As mentioned above, the semiconductor package 10 may include of the chip-via composite substrate 100 having the semiconductor chip 102 provided in the first region R1 and the plurality of through vias 160 provided in the second region R2 around the first region R1. The semiconductor package 10 may further include the first redistribution wiring layer 200, which is provided on the front surface of the chip-via composite substrate 100 and has the first redistribution wirings 202 electrically connected to the chip pads 130 of the semiconductor chip 102 and the through vias 160, and the second redistribution wiring layer 300, which is provided on the backside surface of the chip-via composite substrate 100 and has the second redistribution wirings 302 electrically connected to the through vias 160.

The through vias 160 may be provided to penetrate the chip-via composite substrate 100. The through vias 160 may replace the role of copper posts in a related fan-out wafer level package of a comparative example. Further, the substrate 110 including silicon of the chip-via composite substrate 100 may replace the role of a molding member in a related fan-out wafer level package of comparative example.

Thus, since it is not necessary to perform processes for forming the copper posts and the molding member, packaging processes may be simplified, and since the silicon substrate replaces the existing molding member, the overall thickness of the package may be reduced and the length of signal transmission may be reduced to thereby improve signal transmission characteristics and heat dissipation characteristics.

Hereinafter, a method of manufacturing the semiconductor package of FIG. 1 will be described.

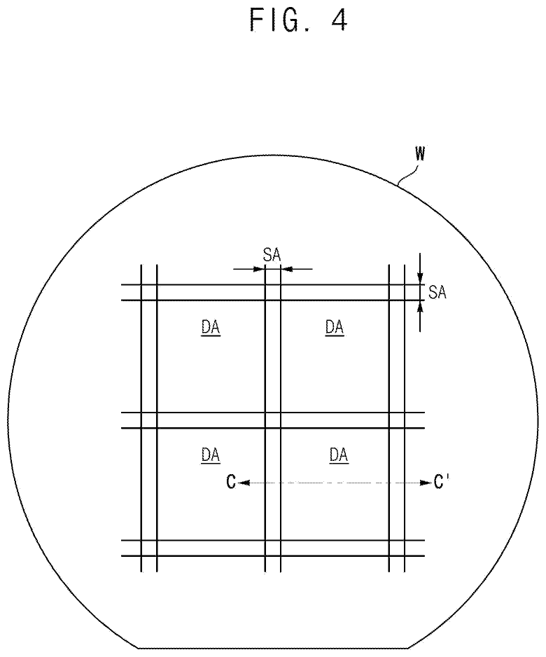

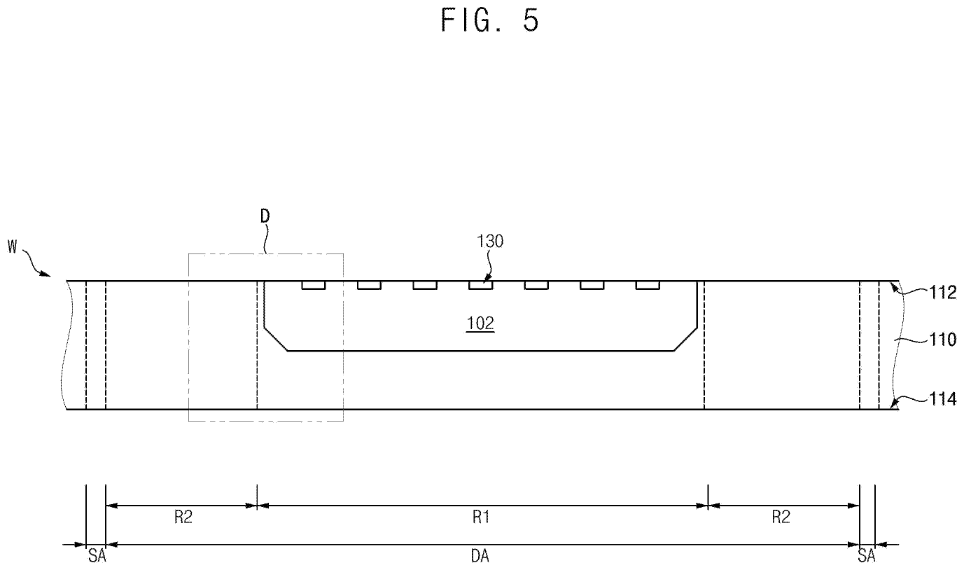

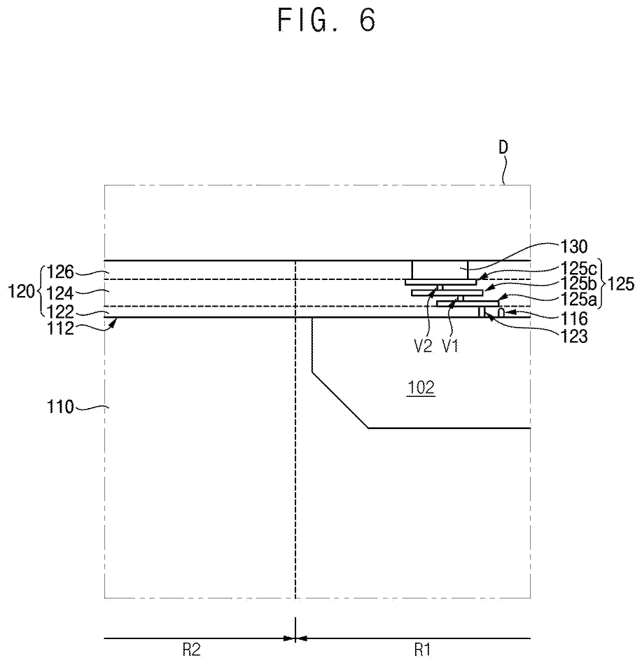

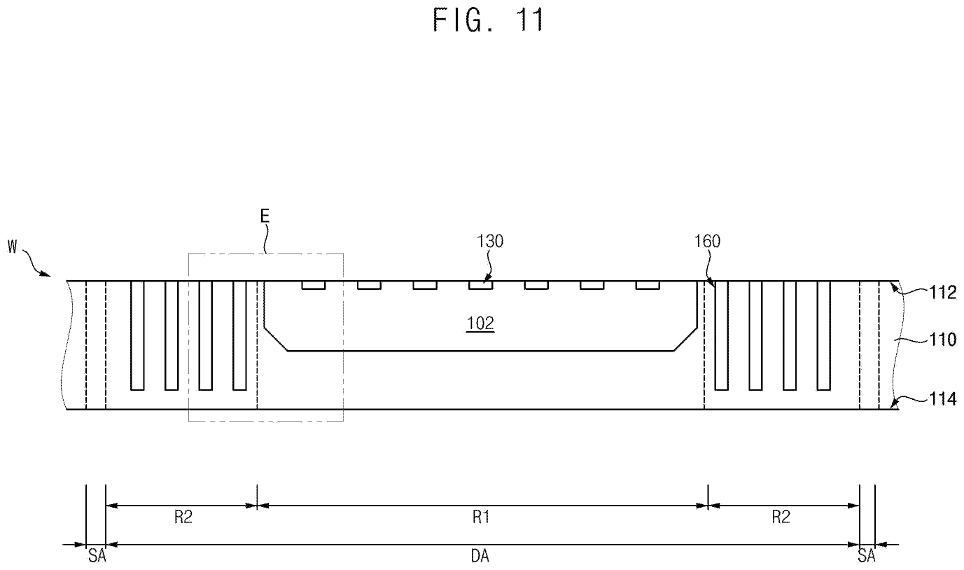

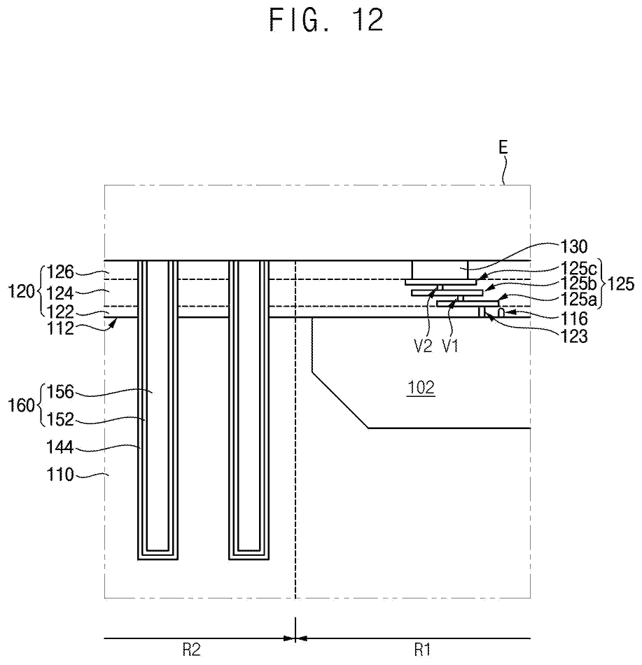

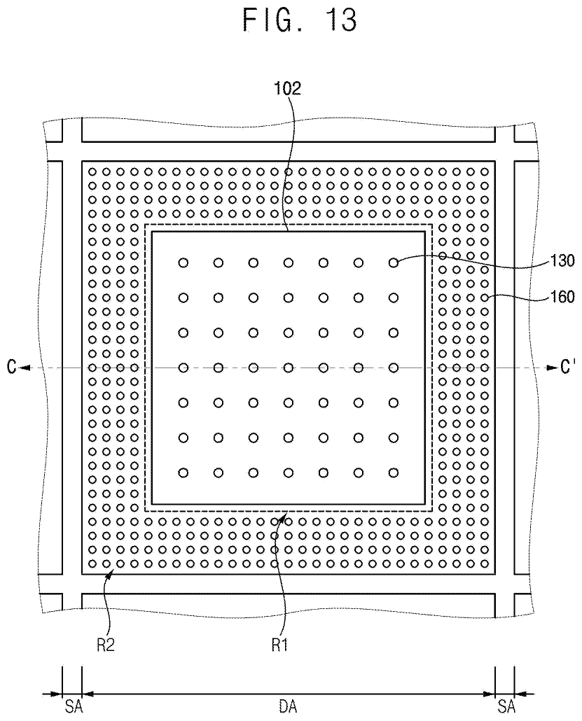

FIGS. 4 to 17 are views illustrating a method of manufacturing a semiconductor package in accordance with an example embodiment of the present inventive concept. FIGS. 5, 11 and 14 to 17 are cross-sectional views illustrating a method of manufacturing a semiconductor package in accordance with an example embodiment of the present inventive. FIGS. 6 to 10 are enlarged cross-sectional views illustrating portion ‘D’ in FIG. 5. FIG. 12 is an enlarged cross-sectional view illustrating portion ‘E’ in FIG. 11. FIG. 13 is a plan view of FIG. 11. FIG. 5 is a cross-sectional view taken along the line C-C′ in FIG. 4.

Referring to FIGS. 4 to 6, first, a wafer W on which a plurality of semiconductor chips (dies) are formed may be prepared.

In some example embodiments of the present inventive concept, the wafer W may include a substrate 110 and a front insulating layer 120 having chip pads 130 on outer surface thereof.

The substrate 110 may have a first surface 112 and a second surface 114 opposite to the first surface 112. The substrate 110 may include a die region DA and a scribe lane region SA surrounding the die region DA. The substrate 110 may be cut along the scribe lane region SA that divides the plurality of die areas DA of the wafer W by a subsequent dicing process (singulation process) to be individualized.

For example, the substrate 110 may include silicon, germanium, silicon-germanium, or III-V compounds, e.g., GaP, GaAs, GaSb, etc. In some example embodiments of the present inventive concept, the substrate 110 may be a silicon-on-insulator (SOI) substrate, or a germanium-on-insulator (GOI) substrate.

The die region DA of the substrate 110 may include a first region R1 and a second region R2 at least partially surrounding the first region R1. The semiconductor wafer W may include a semiconductor chip region 102 provided in the first region R1. Circuit patterns and cells may be formed in the semiconductor chip region 102. The circuit patterns may include, for example, transistors, capacitors, diodes, etc. The circuit patterns may constitute circuit elements for a semiconductor chip such as a logic chip. Accordingly, the semiconductor chip region 102 may serve as a semiconductor chip having a plurality of circuit elements formed therein.

The circuit patterns may be formed on the first surface 112 of the substrate 110 by performing a front end of line (FEOL) process for manufacturing semiconductor devices. A surface of the substrate on which the FEOL process is performed may be referred to as a front side surface of the substrate 110, and a surface opposite to the front side may be referred to as a backside surface.

As illustrated in FIG. 6, the front insulating layer 120 may include an insulation interlayer 122, a metal wiring layer 124 and a passivation layer 126 sequentially formed on the first surface 112 of the substrate 110.

The insulation interlayer 122 may be formed on the first surface 112 of the substrate 110, i.e., the front surface, to cover the circuit patterns 116. The insulation interlayer 122 may be formed to include, for example, silicon oxide or a low dielectric material.

The metal wiring layer 124 may include a plurality of buffer layers and insulating layers alternately formed with each other. For example, the buffer layer may include silicon nitride, silicon carbon nitride, SiCON, etc. The insulating layer may include, for example, silicon oxide, carbon-doped silicon oxide, silicon carbonitride (SiCN), etc.

The metal wiring layer 124 may include a plurality of wirings 125 therein. For example, the metal wiring layer 124 may include a metal wiring structure including the plurality of wirings 125 vertically stacked in the buffer layers and the insulating layers. The plurality of wirings 125 may include a first metal wiring 125a, a first via V1, a second metal wiring 125b, a second via V2 and a third metal wiring 125c. The plurality of wirings 125 may include, for example, aluminum (Al), copper (Cu), tin (Sn), nickel (Ni), gold (Au), platinum (Pt), or an alloy thereof.

The passivation layer 126 may be formed on the metal wiring layer 124 and may expose at least portions of the chip pads 130. The passivation layer 126 may include a plurality of stacked insulating layers. For example, the passivation layer 126 may include an organic passivation layer, which includes an oxide layer, and an inorganic passivation layer, which includes a nitride layer, sequentially stacked. The passivation layer 126 may include, for example, silicon oxide, silicon nitride, silicon carbonitride, etc.

The chip pad 130 may be formed on the third metal wiring 125c which is an uppermost wiring of the metal wire layer 124. The chip pad 130 may be exposed by the passivation layer 126. The first metal wiring 125a may be electrically connected to the circuit pattern 116 through a contact plug 123 penetrating the insulation interlayer 122. Accordingly, the circuit pattern 116 may be electrically connected to the chip pad 130 by the contact plug 123 and the wirings. For example, the chip pad may be made of copper (Cu), aluminum (Al), molybdenum (Mo), titanium (Ti), gold (Au), silver (Ag), chromium (Cr), tin (Sn), nickel (Ni), antimony (Sb), bismuth (Bi), zinc (Zn), indium (In), palladium (Pd), platinum (Pt), or alloys thereof.

The semiconductor chip region 102 as the semiconductor chip 102 may be provided in the first region R1 of the substrate 110, and the chip pads 130 may be provided in the front insulating layer 120 in the first region R1 of the substrate 110 and may be exposed at the outer surface of the front insulating layer 120.

The semiconductor chip 120 may be a logic chip including logic circuits. The logic chip may be a controller that controls memory chips. The semiconductor chip 120 may be a processor chip such as application processor (AP), ASICs serving as a host such as CPU, NPU, GPU, SOC, etc.

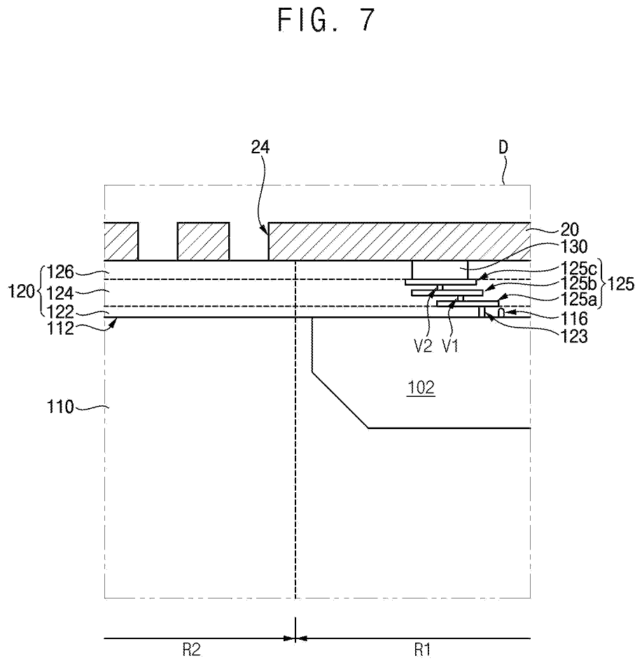

Referring to FIGS. 7 to 13, a plurality of through vias 160 may be formed in the second region R2 of the substrate 110 to partially penetrate the substrate 110.

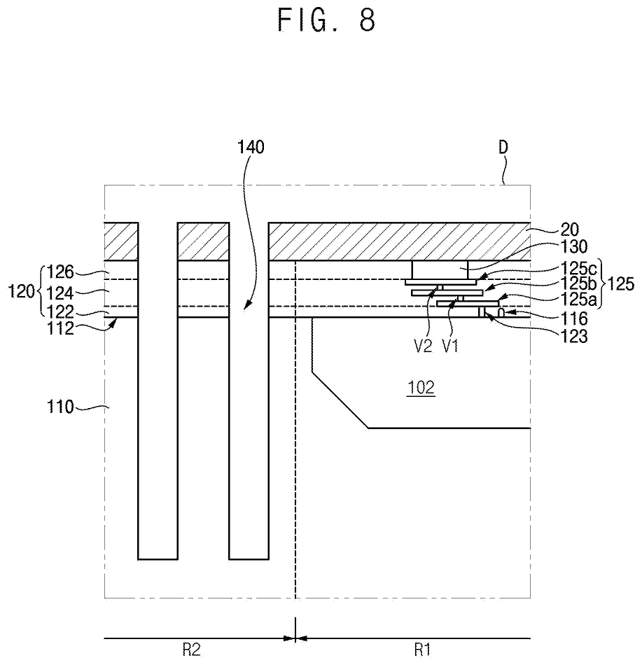

As illustrated in FIGS. 7 and 8, a first photoresist pattern 20, which has a first opening 24 exposing a through via region, may be formed on the passivation layer 126, and the passivation layer 126, the metal wiring layer 124, the insulation interlayer 122 and the substrate 110 may be etched using the first photoresist pattern 20 as an etching mask to form a plurality of trenches 140. Then, the first photoresist pattern 20 may be removed from the substrate 110.

For example, the trenches 140 may be formed by performing a reactive ion etching (RIE) process on the substrate 110. The trench 140 may be formed to have a predetermined depth from the first surface 112 of the substrate 110. For example, the trench 140 may have a circular or rectangular cross-sectional shape. For example, a diameter of the trench may be within a range of about 1 μm to about 50 μm.

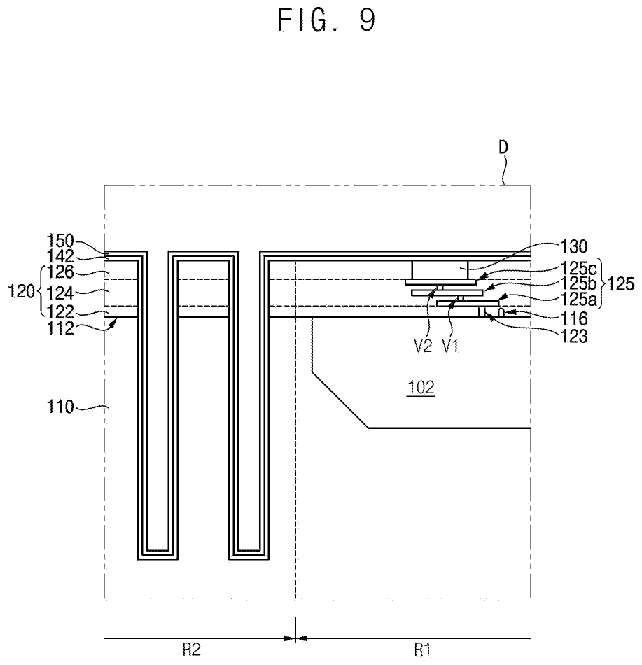

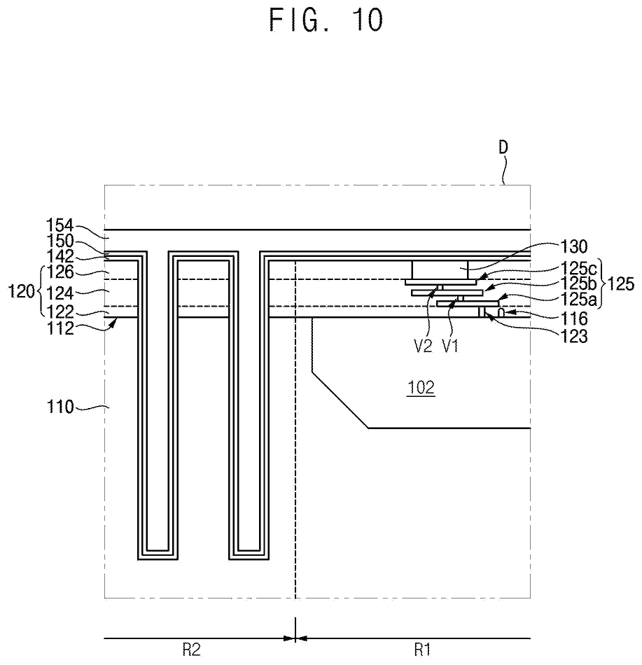

As illustrated in FIGS. 9 and 10, after forming the trenches 140, a barrier layer 142 and a seed layer 150 are sequentially formed on the front insulating layer 120 and on an inner wall of the trench 140. Then, a conductive layer 154 may be formed on the seed layer 150 to sufficiently fill the trench.

The front insulating layer 120 may be formed to include, for example, an oxide such as silicon oxide or a nitride such as silicon nitride. The conductive layer 154 may be formed using, for example, metal such as copper (Cu), aluminum (Al), tungsten (W), or doped polysilicon. When the conductive layer 154 is formed using copper or aluminum, the conductive layer 154 may be formed by an electroplating process after forming the seed layer 150 on the insulating layer 120. In addition, the barrier layer 142 may be formed to include a metal nitride such as titanium nitride, tantalum nitride, tungsten nitride, copper nitride, aluminum nitride, etc.

As illustrated in FIGS. 1I to 13, the conductive layer 154 and the insulating layer 120 may be planarized until the front insulating layer 120, which is on the first surface 112 of the substrate 110, is exposed, to form the through vias 160 that fill the trenches 140. The through via 160 may include a seed layer pattern 152, a barrier layer pattern 144 and a conductive layer pattern 156.

Thus, a chip-via composite substrate, where the semiconductor chip 102 is provided in the first region R1 of the substrate 110 and the plurality of through vias 160 are formed in the second region R2 of the substrate 110, may be formed.

The plurality of through vias 160 may be formed in the second region R2 of the substrate 110 to penetrate the front insulating layer 120 and partially penetrate the substrate 110. One end portion of the through via 160 may be exposed from the front insulating layer 120. In addition, the plurality of chip pads 130 may be exposed from the front insulating layer 120 in the first region R1 of the substrate 110.

The plurality of through vias 160 may be referred to as through silicon vias (TSVs). The semiconductor chip region 102 may be provided in the first region R1 that is a central region of the die region DA, and the through vias 160 may be arranged in an array form in the second region R2 that is a fan-out region outside the semiconductor chip region 102.

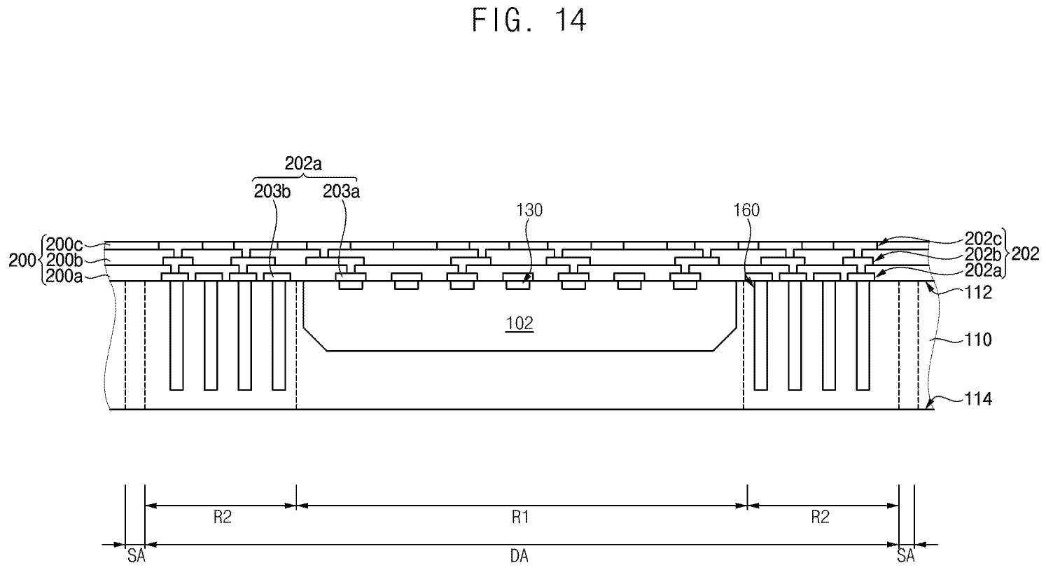

Referring to FIG. 14, a first redistribution wiring layer 200 having first redistribution wirings 202, which is electrically connected to the chip pads 130 and the through vias 160, may be formed on the first surface 112 of a substrate 110.

In some example embodiments of the present inventive concept, first lower redistribution wirings 202a may be formed on at least portions of the chip pads 130 and the through vias 160 exposed from the front insulating layer 120, and a first lower insulating layer 200a may be formed on the front insulating layer 120 to cover the first lower redistribution wirings 202a.

For example, the first lower redistribution wirings 202a may be formed by an electroplating process. After forming a seed layer on the front insulating layer 120, the seed layer may be patterned and an electroplating process may be performed to form the first lower redistribution wirings 202a. The first lower redistribution wirings 202a may include, for example, aluminum (Al), copper (Cu), tin (Sn), nickel (Ni), gold (Au), platinum (Pt), or an alloy thereof.

The first lower insulating layer 200a may include, for example, a polymer or a dielectric layer. For example, the first lower insulating layer 200a may be formed by a vapor deposition process, a spin coating process, etc.

Then, the first lower insulating layer 200a may be patterned to form openings that expose the first lower redistribution wirings 202a, and second lower redistribution wirings 202b may be formed on the first lower insulating layer 200a to be electrically connected to the first lower redistribution wirings 202a through the openings.

For example, a seed layer may be formed on a portion of the first lower insulating layer 200a and in the opening, the seed layer may be patterned, and an electroplating process may be performed to form the second lower redistribution wirings 202b. Accordingly, at least a portion of the second lower redistribution wiring 202b may contact the first lower redistribution wiring 202a through the opening. For example, at least a portion of the second lower redistribution wiring 202b may directly contact the first lower redistribution wiring 202a through the opening.

Similarly, after the second lower insulating layer 200b is formed on the first lower insulating layer 200a to cover the second lower redistribution wirings 202b, the second lower insulating layer 200b may be patterned to form openings that expose the second lower redistribution wirings 202b. Then, third lower redistribution wirings 202c may be formed on the second lower insulating layer 200b to be electrically connected to the second lower redistribution wirings 202b through the openings.

Then, after a third lower insulating layer 200c is formed on the second lower insulating layer 200b to cover the third lower redistribution wirings 202c, the third lower insulating layer 200c may be patterned to form openings that expose the third lower redistribution wirings 202c. The third lower redistribution wirings 202c exposed by the openings may be outermost redistribution wirings. A portion of the outermost redistribution wiring may include a redistribution pad portion. For example, a bump pad such as a UBM may be formed on the redistribution pad portion.

Thus, the first redistribution wiring layer 200 having the first redistribution wirings 202 as a front redistribution wiring layer (FRDL) may be formed on the front insulating layer 120 on the first surface 112 of the substrate 100. The first redistribution wiring layer 200 may include the stacked first, second and third lower insulating layers 200a, 200b and 200c and the first, second and third lower redistribution wirings 202a, 202b and 202c in the first, second and third lower insulating layers 200a, 200b and 200c. The first redistribution wiring 202 may include the first, second and third lower redistribution wirings 202a, 202b and 202c. The second redistribution wiring layer 300 may have a first surface and a second surface opposite to the first surface.

The first lower redistribution wirings 202a of the first redistribution wiring 202 may include first uppermost redistribution wirings 203a and second uppermost redistribution wirings 203b. The first uppermost redistribution wirings 203a may be arranged in the first region R1 of the substrate 110 and electrically connected to the chip pads 130 of the semiconductor chip 102, and the second uppermost redistribution wirings 203b may be arranged in the second region R2 of the substrate 110 and electrically connected to the through vias 160. Additionally, the first and second uppermost redistribution wirings 103a and 103b may be electrically connected to each other.

The numbers, sizes, arrangements, etc. of the lower insulating layers 200a, 200b, and 200c and the lower redistribution wirings 202 of the first redistribution wiring layer 200 are provided as examples, and it will be understood that the present inventive concept is not limited thereto.

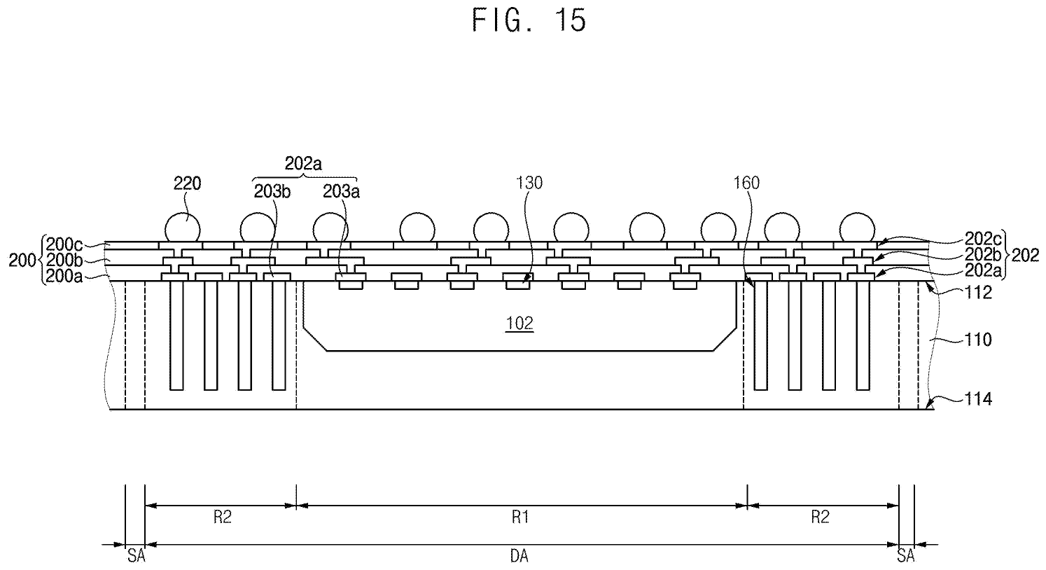

Referring to FIG. 15, external connection members 220 may be formed on the first redistribution wiring layer 200 to be electrically connected to the first redistribution wirings 202.

For example, a solder ball or a solder bump as the external connection member 220 may be formed on a portion of the third lower redistribution wiring 202c. The external connection members 220 may be respectively formed on the bump pads that are on an outer surface of the first redistribution wiring layer 200 by a solder ball attach process. In addition, the external connecting members may be formed by a plating process, a screen printing method, a deposition method, etc.

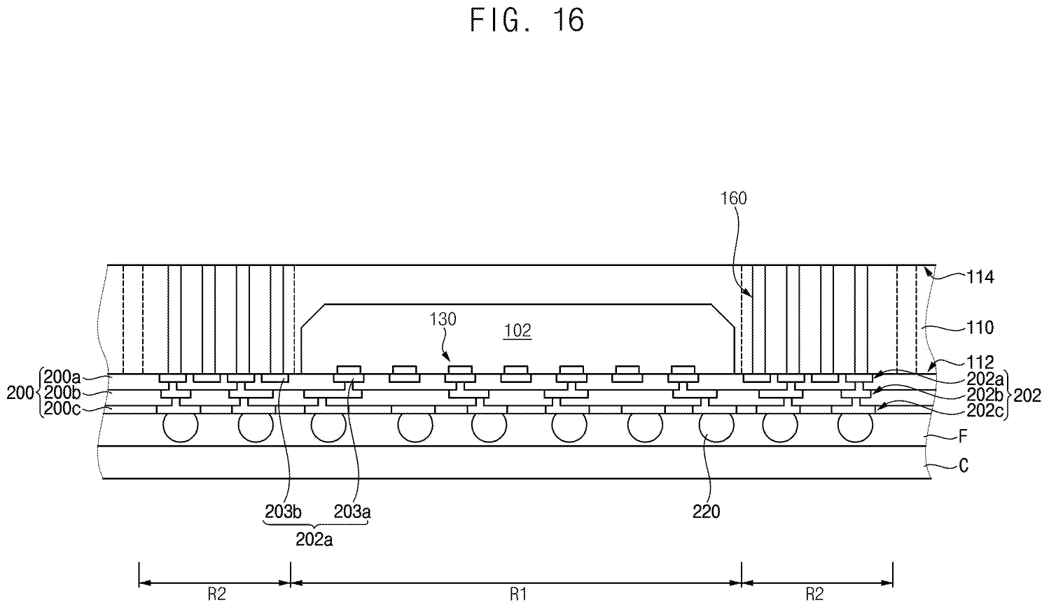

Referring to FIG. 16, the structure of FIG. 15 may be turned over, and then, the second surface 114 of the substrate 110 may be partially removed to expose the other end portions of the through vias 160.

In some example embodiments of the present inventive concept, the backside surface, that is, the second surface 114 of the substrate 110 may be polished using a substrate support system (WSS). The second surface 114 of the substrate 110 may be removed until a portion of the through via 160 is exposed. For example, the first redistribution wiring layer 200 may be attached on a carrier substrate C using an adhesive film F, and the second surface 114 of the substrate 110 may be partially removed by an etch back process, a chemical mechanical polishing (CMP) process, etc.

Accordingly, a thickness of the substrate 110 may be reduced to a desired thickness. For example, the substrate 110 may have the thickness ranging from about 100 μm to about 800 μm. Additionally, the other end portion of the through via 160 may be exposed from the second surface 114 of the substrate 110.

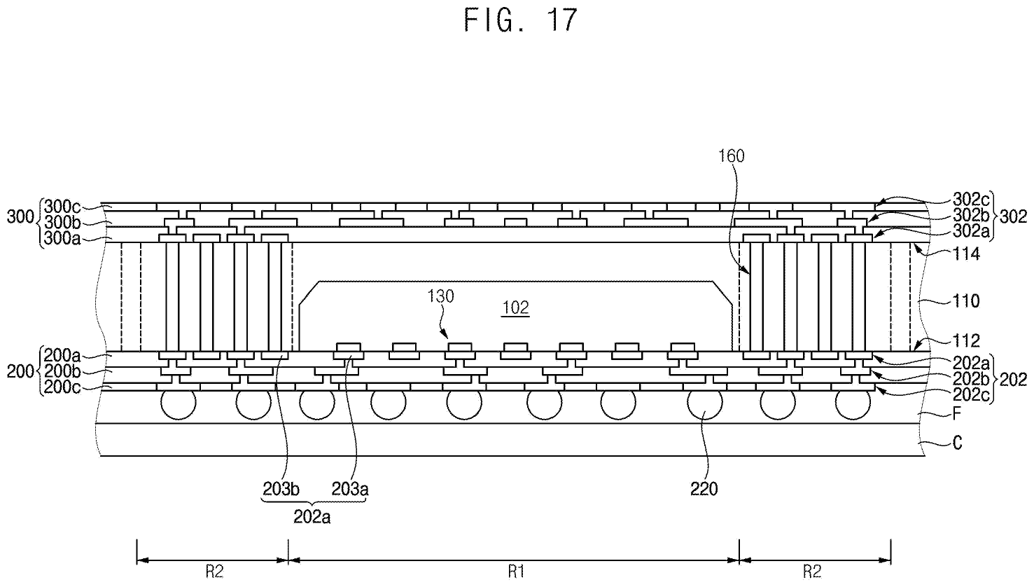

Referring to FIG. 17, a second redistribution wiring layer 300 having second redistribution wirings 302 that are electrically connected to the through vias 160 may be formed on the second surface 114 of the substrate 110.

In some example embodiments of the present inventive concept, first upper redistribution wirings 302a may be formed on at least portions of the through vias 160 that are exposed from the second surface 114 of the substrate 110, and a first upper insulating layer 300a may be formed on the second surface 114 of the substrate 110 to cover the first upper redistribution wirings 302a.

For example, the first upper redistribution wirings 302a may be formed by an electroplating process. After a seed layer is formed on the second surface 114 of the substrate 110, the seed layer may be patterned and an electroplating process may be performed to form the first upper redistribution wirings 302a. The first upper redistribution wiring may include, for example, aluminum (Al), copper (Cu), tin (Sn), nickel (Ni), gold (Au), platinum (Pt) or an alloy thereof.

The first upper insulating layer 300a may include, for example, a polymer or a dielectric layer. For example, the first upper insulating layer 300a may be formed by a vapor deposition process, a spin coating process, etc.

Then, the first upper insulating layer 300a may be patterned to form openings that expose the first upper redistributable wirings 302a, and second upper redistribution wirings 302b may be formed on the first upper insulating layer 300a to be electrically connected to the first upper redistribution wirings 301b through the openings.

For example, a seed layer may be formed on a portion of the first upper insulating layer 300a and in the opening, the seed layer may be patterned and an electroplating process may be performed to form the second upper redistribution wirings 302b. Accordingly, at least a portion of the second upper redistribution wiring 302b may contact the first upper redistribution wiring 302a through the opening. For example, at least a portion of the second upper redistribution wiring 302b may directly contact the first upper redistribution wiring 302a through the opening.

Similarly, after a second upper insulating layer 300b is formed on the first upper insulating layer 300a to cover the second upper redistribution wirings 302b, the second upper insulating layer 300b may be patterned to form openings that expose the second upper redistribution wirings 302b. Then, third upper redistribution wirings 302c may be formed on the second upper insulating layer 300b to be electrically connected to the second upper redistribution wirings 302b through the openings.

Then, a third upper insulating layer 300c may be formed on the second upper insulating layer 300b to cover the third upper redistribution wirings 302c, the third upper insulating layer 300c may be patterned to form openings that expose the third upper redistribution wirings 302c. The third upper redistribution wirings 302c exposed by the openings may be outermost redistribution wirings. A portion of the outermost redistribution wirings may include a redistribution pad portion. For example, a bump pad such as a UBM may be formed on the redistribution pad portion.

Thus, the second redistribution wiring layer 300 having the second redistribution wirings 302 as a backside redistribution wiring layer (BRDL) may be formed on the second surface 114 of the substrate 110. The second redistribution wiring layer 300 may include the stacked first, second and third upper insulating layers 300a, 300b and 300c and the second redistribution wirings 302 in the stacked first, second and third upper insulating layers 300a, 300b and 300c. The second redistribution wiring 302 may include the first, second and third upper redistribution wirings 302a, 302b and 302c.

The numbers, sizes, arrangements, etc. of the upper insulating layers 300a, 300b and 300c and the upper redistribution wirings 302a, 302b and 302c of the second redistribution wiring layer 300 are provided as examples, and it will be understood that the present inventive concept is not limited thereto.

Then, the wafer W may be cut along the scribe lane region SA to form the individualized semiconductor package of FIG. 1. The wafer W may be cut by a sawing process.

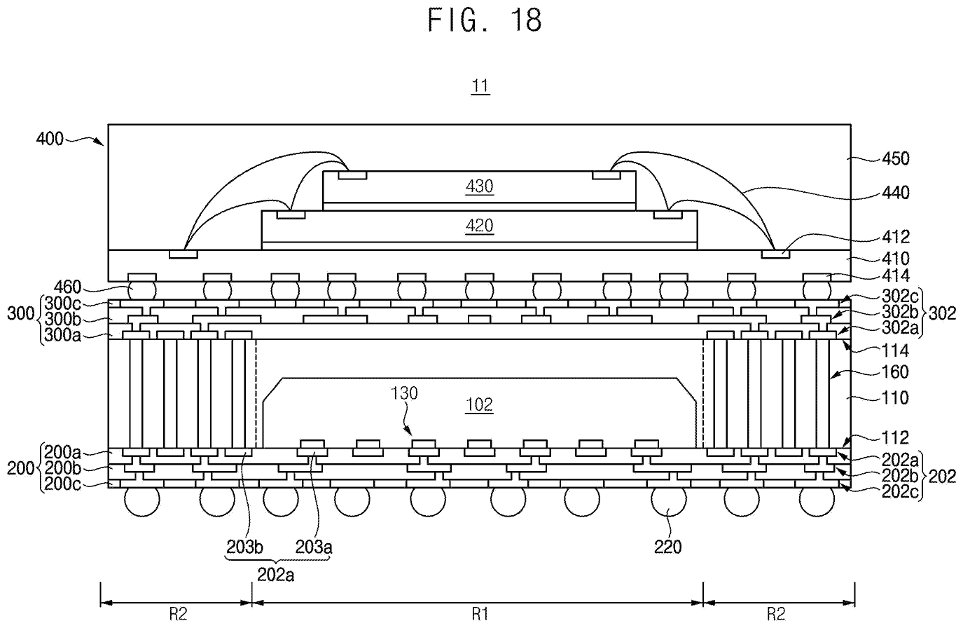

FIG. 18 is a cross-sectional view illustrating a semiconductor package in accordance with an example embodiment of the present inventive concept. The semiconductor package may be substantially the same as the semiconductor package described with reference to FIGS. 1 to 3 except for an additional second package. Accordingly, same reference numerals may be used to refer to the same or like elements throughout the specification and any further repetitive explanation concerning the above elements may be omitted or briefly discussed.

Referring to FIG. 18, a semiconductor package 11 may include a first package and a second package 400 stacked on the first package. The semiconductor package 11 may further include a heat sink stacked on the second package 400. The first package may include a chip-via composite substrate 100, which has a semiconductor chip 102 and a plurality of through vias 160, a first redistribution wiring layer 200 and a second redistribution wiring layer 300. The first package may be substantially the same as or similar to the unit package described with reference to FIG. 1.

In some example embodiments of the present inventive concept, the second package 400 may be stacked on the first package via conductive connection members 460.

The second package 400 may include a second package substrate 410, second and third semiconductor chips 420 and 430, which are mounted on the second package substrate 410, and a sealing member 450 disposed on the second package substrate 410 and covering the second and third semiconductor chips 420 and 430.

The second package 400 may be stacked on the first package via the conductive connection members 460. For example, the conductive connection members 460 may include solder balls, conductive bumps, etc.

The conductive connection member 460 may be disposed between a bump pad, which is on a third upper redistribution wiring 302c of a second redistribution wiring layer 300, and a second substrate pad 414 of the second package substrate 410. Accordingly, the first package and the second package 400 may be electrically connected to each other by the conductive connection members 460.

The second and third semiconductor chips 420 and 430 may be stacked on the second package substrate 410 by adhesive members. Bonding wires 440 may connect chip pads of the second and third semiconductor chips 420 and 430 to first substrate pads 412 of the second package substrate 410. The second and third semiconductor chips 420 and 430 may be electrically connected to the second package substrate 410 by the bonding wires 440.

Although the second package 400 includes two semiconductor chips mounted by a wire bonding method, it will be understood that the number of semiconductor chips in the second package 400 and the mounting method are not limited thereto.

The second semiconductor chip 420 may include a memory chip including a memory circuit. For example, the second semiconductor chip 420 may include volatile memory devices such as SRAM devices, DRAM devices, etc., and non-volatile memory devices such as flash memory devices, PRAM devices, MRAM devices, RRAM devices, etc.

In some example embodiments of the present inventive concept, the heat sink may be provided on the second package 400 to dissipate heat from the first package and second package 400 to the outside. The heat sink may be attached on the second package 400 by using a thermal interface material (TIM).

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a chip-via composite substrate including a substrate, a semiconductor chip, and a plurality of through vias, wherein the substrate has a first surface and a second surface opposite to the first surface and includes a first region and a second region around the first region, wherein the semiconductor chip is provided in the first region and has chip pads, which are formed on the first surface, and circuit patterns that are electrically connected to the chip pads, and wherein the plurality of through vias is provided in the second region and penetrate the substrate;
a first redistribution wiring layer provided on the first surface of the substrate and having first redistribution wirings that are electrically connected to the chip pads and the through vias; and
a second redistribution wiring layer provided on the second surface of the substrate and having second redistribution wirings that are electrically connected to the through vias.

2. The semiconductor package of claim 1, wherein the first redistribution wirings include first uppermost redistribution wirings, which are electrically connected to the chip pads in the first region, and second uppermost redistribution wirings, which are electrically connected to the through vias in the second region.

3. The semiconductor package of claim 1, wherein the substrate includes a silicon material.

4. The semiconductor package according to claim 1, wherein a thickness of the substrate is within a range of about 100 μm to about 800 μm.

5. The semiconductor package of claim 1, wherein a diameter of each of the through vias is within a range of about 1 μm to about 50 μm.

6. The semiconductor package of claim 1, wherein the chip-via composite substrate further comprises a front insulating layer disposed on the first surface of the substrate and having the chip pads disposed adjacent to an outer surface of the front insulating layer.

7. The semiconductor package of claim 6, wherein the through vias penetrates the front insulating layer.

8. The semiconductor package of claim 6, wherein the first redistribution wiring layer is provided on the front insulating layer.

9. The semiconductor package of claim 6, wherein the front insulating layer includes:
an insulation interlayer provided on the first surface of the substrate and covering the circuit patterns;
a metal wiring layer provided on the insulation interlayer and having wirings that are electrically connected to the circuit patterns; and
a passivation layer provided on the metal wiring layer and exposing at least portions of the chip pads that are electrically connected to the wirings.

10. The semiconductor package of claim 1, further comprising:
external connection members provided on an outer surface of the first redistribution wiring layer and electrically connected to the first redistribution wirings.

11. A semiconductor package, comprising:
a chip-via composite substrate including a substrate, a front insulating layer, and a plurality of through vias, wherein the substrate has a first surface and a second surface opposite to the first surface and includes a first region and a second region around the first region, wherein the front insulating layer is provided on the first surface of the substrate and has chip pads adjacent to an outer surface of the front insulating layer, wherein circuit patterns are provided on the first surface of the substrate and are electrically connected to the chip pads, and wherein the plurality of through vias is provided in the second region and penetrate the front insulating layer and the substrate;
a first redistribution wiring layer provided on the first surface of the substrate and having first redistribution wirings that are electrically connected to the chip pads and the through vias; and
a second redistribution wiring layer provided on the second surface of the substrate and having second redistribution wirings that are electrically connected to the through vias.

12. The semiconductor package of claim 11, wherein the substrate includes a silicon material.

13. The semiconductor package of claim 11, wherein a thickness of the substrate is within a range of about 100 μm to about 800 μm.

14. The semiconductor package of claim 11, wherein each of the through vias has a diameter within a range of about 1 μm to about 50 μm.

15. The semiconductor package of claim 11, wherein the first redistribution wiring layer is provided on the front insulating layer.

16. The semiconductor package of claim 11, wherein the front insulating layer includes:
an insulation interlayer provided on the first surface of the substrate and covering the circuit patterns;
a metal wiring layer provided on the insulation interlayer and having wirings that are electrically connected to the circuit patterns; and
a passivation layer provided on the metal wiring layer and exposing at least portions of the chip pads that are electrically connected to the wirings.

17. The semiconductor package of claim 11, wherein the first redistribution wirings include first uppermost redistribution wirings, which are electrically connected to the chip pads in the first region, and second uppermost redistribution wirings, which are electrically connected to the through vias in the second region.

18. The semiconductor package of claim 11, further comprising:
external connection members provided on an outer surface of the first redistribution wiring layer and electrically connected to the first redistribution wirings.

19. The semiconductor package of claim 11, further comprising:
a second package disposed on the second redistribution wiring layer, and having at least one second semiconductor chip mounted thereon and electrically connected to the second redistribution wirings.

20. A semiconductor package, comprising:
a chip-via composite substrate having a first surface and a second surface opposite to the first surface, and including a semiconductor chip and a plurality of through vias, wherein the semiconductor chip is provided in a first region of the chip-via composite substrate and has chip pads that are exposed from the first surface, and wherein the plurality of through vias are provided in a second region of the chip-via composite substrate and extend from the first surface to the second surface;
a first redistribution wiring layer provided on the first surface of the chip-via composite substrate and having first redistribution wirings that are electrically connected to the chip pads and the through vias; and
a second redistribution wiring layer provided on the second surface of the chip-via composite substrate and having second redistribution wirings that are electrically connected to the through vias.
